(19) United States
(12) Patent Application Publication
(10) Pub. No.: US 2026/0363119 A1
(43) Pub. Date: Nov. 12, 2026

(54) Package and Method of Manufacturing the Package

(71) Applicant: AT&S Austria Technologie & Systemtechnik Aktiengesellschaft, Leoben (AT)

(72) Inventor: Jeesoo MOK, Leoben (AT)

(21) Appl. No.: 19/125,735

(22) PCT Filed: Sep. 27, 2023
(86) PCT No.: PCT/EP2023/076773

§ 371 Date: Apr. 29, 2025

(30) Foreign Application Priority Data
Oct. 31, 2022 (CN) 202211350647.8

(51) Int. Cl. H10W 70/685; H10W 70/05; H10W 70/692; H10W 70/695; H10W 90/00

(52) U.S. Cl. CPC H10W 70/686; H10W 70/095; H10W 90/724; H10W 70/692; H10W 70/695

(57) ABSTRACT

A package and a method of manufacturing the package. The package includes a carrier body having a cavity, a glass inlay embedded in the cavity of the carrier body, a patterned metal layer on a main surface of the glass inlay, and an electronic component mounted above the glass inlay.

### CROSS REFERENCE TO RELATED APPLICATIONS

This application is a national stage application, filed under 35 U.S.C. § 371, of International Patent Application No. PCT/EP2023/076773, filed on Sep. 27, 2023, claiming priority of the Patent Application No. 202211350647.8, filed on Oct. 31, 2022, with the China National Intellectual Property Administration, the disclosures of which are hereby incorporated by reference herein in their entirety.

### TECHNICAL FIELD

The disclosure relates to a package and a method of manufacturing a package.

### TECHNOLOGICAL BACKGROUND

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming component carrier-based packages are still challenging.

### SUMMARY

There may be a need to provide a compact and reliable package.

This object is solved by the subject matter according to the independent claims. Further embodiments are described by the dependent claims.

According to an embodiment of the disclosure, a package is provided which comprises a carrier body having a cavity, a glass inlay embedded in the cavity of the carrier body, a patterned metal layer on a main surface of the glass inlay, and an electronic component mounted above the glass inlay.

According to another embodiment of the disclosure, a method of manufacturing a package is provided, wherein the method comprises providing a carrier body with a cavity, embedding a glass inlay in the cavity of the carrier body, forming a patterned metal layer on a main surface of the glass inlay, and mounting an electronic component above the glass inlay.

### OVERVIEW OF EMBODIMENTS

In the context of the present application, the term “package” may particularly denote any support structure which is capable of accommodating one or more components thereon and/or therein for providing mechanical support and/or electrical connectivity. In other words, a package may be configured as a mechanical and/or electronic carrier for components. In particular, a package may be a component carrier-type device. Such a component carrier may be an IC (integrated circuit) substrate or a printed circuit board (PCB). A component carrier may also be a hybrid board combining different types of component carriers. A role of packaging is to house a component, supply it with electricity and act as an interface between the component and the rest of the elements in the system. Moreover, a function of a package may be to protect the component from dirt and physical impact and also fulfill thermal management requirements. A package may comprise one or more components, component carriers, a redistribution layer (RDL) structure, input elements and/or output elements, etc. Furthermore, advanced package technology may avoid performance limitations for components. Embodiments of the present disclosure may provide a technology to conform to a semiconductor package technology development trend and to meet even demanding performance requirements of packages from electricity transmission, thermal management, power management and environment protection with low effort.

In the context of the present application, the term “carrier body” may particularly denote a support structure of the package. In particular, said carrier body may be a core or a component carrier (such as a printed circuit board or an integrated circuit substrate). Further examples of the carrier body are a ceramic carrier body (such as aluminum nitride and/or aluminum oxide), and a carrier body made of a material comprising a semiconductor (such as silicon oxide, silicon, silicon carbide, gallium nitride, etc.). The carrier body also can be a metal plate or a glass carrier body.

In the context of the present application, the term “glass inlay” may particularly denote a body configured for being inserted into a destination and comprising glass as main constituent. For example, the glass inlay may be a block or plate. The major material component (in particular the material component of the glass inlay providing the highest weight percentage) of the glass inlay is glass, for example silicon-based glass, in particular soda lime glass, and/or boro-silicate glass and/or alumo-silicate glass and/or lithium silicate glass and/or alkaline free glass. For instance, at least 90 weight percent of the glass inlay may be glass. For example, the glass inlay may consist only of glass, apart from a patterned metal layer thereon. It is, however, also possible that the glass inlay comprises one or more additional other materials. For instance, further electrically conductive (for example comprising metal and/or metal alloys, for example, copper and/or tin and/or bronze) structures (such as wiring traces and/or vertical through connections) may be integrated in a main glass body of the glass inlay and/or may be formed on a surface of a main glass body. The glass inlay can function as the interconnection between component carrier and component with electrically conductive structure and electrically insulating structure. Moreover, the glass inlay can also be provided with a heat dissipation and power supply function with specific structure inside. It is, however, also possible that the glass inlay comprises ceramic material, for example aluminum nitride and/or aluminum oxide and/or silicon nitride and/or boron nitride and/or tungsten comprising ceramic material. Additionally and/or alternatively, the glass inlay may comprise semi-conductive material, for example silicon and/or germanium and/or silicon oxide and/or germanium oxide and/or silicon carbide and/or gallium nitride. Yet it is further possible that the glass inlay may comprise inorganic material, which is not listed in the above-mentioned examples, such as: MOS₂, CuGaO₂, AgAlO₂, LiGaTe₂, AgInSe₂, CuFeS₂, BeO.

In the context of the present application, the term “embedded” may particularly denote fully embedded or only partially embedded. In a fully embedded embodiment, the entire vertical spatial range between an upper end and a lower end of the glass inlay is located inside of the carrier body. In one embodiment, the upper end of the at least partially embedded glass inlay may be in alignment with an upper main surface of the carrier body and/or the lower end of the at least partially embedded glass inlay may be in alignment with a lower main surface of the carrier body. In another embodiment, the upper end of the at least partially embedded glass inlay may be located below an upper main surface of the carrier body and/or the lower end of the at least partially embedded glass inlay may be located above a lower main surface of the carrier body. However, it is also possible that an upper end portion of the glass inlay protrudes vertically beyond an upper main surface of the carrier body and/or that a lower end portion of the glass inlay protrudes vertically below an upper main surface of the carrier body.

In the context of the present application, the term “cavity” may particularly denote a blind hole or a through hole in the carrier body shaped and dimensioned for accommodating a glass inlay entirely or partially therein.

In the context of the present application, the term “patterned metal layer” may particularly denote a planar layer made of a metallic material and being structured. For instance, the patterned metal layer may comprise at least two island-shaped metallic spots (such as pads) and/or may comprise at least one elongate or curved wiring element. The patterned metal layer may be formed directly on a main surface of the glass inlay or may be spaced with respect to the main surface of the glass inlay by at least one intermediate element. Preferably, the patterned metal layer is only a single layer of metallic material which is structured in accordance with an electric connection characteristic of the surface mounted electronic component and/or the package main body.

In the context of the present application, the term “main surface” of a body may particularly denote one of two outermost (and in many cases largest) opposing surfaces of the body. The main surfaces may be connected by circumferential side walls. The thickness of a glass inlay, or another body having two opposing main surfaces, may be defined by the distance between the two opposing main surfaces.

In the context of the present application, the term “electronic component” may particularly denote a member fulfilling an electronic task. Such an electronic component may be an active component such as a semiconductor chip comprising a semiconductor material, in particular as a primary or basic material. The electronic component may also be a passive component, for instance a capacitor or an inductor.

In the context of the present application, the term “electronic component above the glass inlay” may particularly denote that the electronic components may be vertically spaced with respect to the glass inlay with at least the patterned metal layer in between. Optionally, at least one additional structure may be interposed between the glass inlay and the electronic component. In particular, such an additional structure may be a build-up of one or more layers structures (for instance a laminated layer stack, a redistribution structure, etc.). An electronic component mounted above the glass inlay may be, in an embodiment, located between its lateral ends inside of a lateral extension of the glass inlay.

According to an embodiment of the disclosure, a package comprises a carrier body and a glass inlay embedded in the carrier body. A patterned metal layer may be provided on the glass inlay and may be preferably electrically connected with a surface mounted electronic component on top of the package. Advantageously, the glass inlay may have very flat surfaces so that a planarization stage during processing may be dispensable and fine line processing thereon may be fully supported. Furthermore, the glass inlay may have a high degree of thermal stability so that thermally-caused undesired phenomena such as thermal stress, warpage and delamination will not impact the package significantly. This can make the whole package stable with a controllable change of the dimension of the package (such as shrinkage would be less). Furthermore, glass material may show a low DK and low DF behavior with good dielectric property and may therefore support low loss high-frequency (in particular improving radio frequency, RF) and high-speed applications as well as high performance computing application with good signal integrity and low loss. Further advantageously, a patterned metal layer may be formed with highest accuracy on the glass inlay so that the smooth surface of the glass inlay leads to a high spatial precision and definition of substructures of the patterned metal layer, in particular for very fine line structuring formation. Consequently, electrically coupling a surface mounted electronic component directly or indirectly by a patterned metal layer formed on a glass inlay may result in a well-defined package configuration which can be manufactured with high accuracy and in small dimensions. A further advantage of a package according to an embodiment is that the glass inlay can be embedded in a surrounding carrier body. As a result, the dimension of the glass body may be adapted to the dimension of an electronic component mounted above. Such an adaptation may lead to advantageous properties of the obtained package. To put it shortly, an embodiment may provide a chip-scale glass body with an electronic component being scaled in a similar way as the glass inlay. Instead of a full glass core extending substantially over the entire width of the package, an embodiment of the disclosure may provide a simple carrier body (in particular a standard core) with one or multiple holes and one or more embedded glass inlays being provided only where needed (in particular directly below a respective surface mounted electronic component). This combines low manufacturing effort with the benefits of glass below a surface mounted electronic component. More important, this configuration may help the assembly between the component and the component carrier with good bonding performance (and consequently less possible delamination due to coefficient of thermal expansion (CTE) mismatch compared to a normal package with a component directly mounted on the organic component carrier). Beyond this, the glass with its high stiffness can reinforce the stiffness of the whole package. Additionally, the glass inlay with a pattern or redistribution layer (RDL) on its surface can also enhance the signal integrity with better electricity transmission due to the good dielectric property.

In the following, further example embodiments of the package and the method will be explained.

In an embodiment, the glass inlay may be silicon-based (for instance may be silicon glass formed of almost pure silicon, i.e. silicon dioxide, SiO₂) and the electronic component may be silicon-based (for example a silicon chip). When the electronic component is a silicon chip and the glass inlay comprises a silicon-based glass, the common silicon material of the glass inlay and of the component may lead to only a very small CTE (coefficient of thermal expansion) mismatch between glass inlay and electronic component. This may result, in turn, in a strong suppression of undesired phenomena such as warpage and delamination.

Glass material, and in particular silicon-based glass material, of the glass inlay has the further advantage that not only a CTE mismatch with respect to an electronic component of the package may be small, but also the absolute CTE value of glass material may be relatively small. Consequently, the embedded glass inlay will not cause excessive thermal stress in the event of temperature changes. This may lead, in turn, to a good warpage and delamination behavior of the package.

In an embodiment, the carrier body comprises an organic core. In this context, a core may be a component carrier-type (in particular printed circuit board-type or integrated circuit substrate-type) support body. Such a core may be made for instance of fully cured resin with reinforcing particles, such as glass spheres, therein. Also, electrically conductive layers structures, such as one or more patterned metal layers on a respective main surface of a core and/or one or more vertical through connections extending entirely through the core, may form part of the core. The core may comprise an organic material. An organic material may be a chemical compound that contains carbon-hydrogen bonds. For example, the organic core may comprise an organic resin material, an epoxy material, etc. Configuring the carrier body as a component carrier-type organic core may allow to form the carrier body with low effort and appropriate to fulfill both a mechanical support function and an electric connection control. An organic core with a through hole-type cavity may accommodate the glass inlay in the cavity and may simultaneously establish an electric connection between a portion above and below the organic core by one or more electrically conductive through connections extending through the organic core.

In an embodiment, the glass inlay is free of electrically conductive vertical through connections. For example, the glass inlay may consist only of glass and the patterned metal layer thereon. By omitting electrically conductive connection structures inside the glass inlay, provision of the glass inlay can be possible with very low effort. No cumbersome processing thereof may be necessary. In such an embodiment, the entire electricity (what concerns electric signals and electric power) may be guided through the carrier body and the patterned metal layer, whereas the glass inlay may then be electrically passive.

Glass as the main material of the glass inlay has significant advantages: On the one hand, a glass inlay may be provided with an extremely flat and smooth surface, so that fine line structuring of the patterned metal layer on the glass inlay may be possible. No planarization of a glass inlay is necessary before integrating it into the package. Apart from this, glass is highly robust against temperature changes and thereby mechanically stabilizes the entire package with little change of dimension. The pronounced temperature stability and the very smooth surface of a glass inlay allow the manufacture of packages with high yield.

In another embodiment, the package comprises at least one electrically conductive connection structure in an interior of the glass inlay. For instance, such an electrically conductive connection structure may be a vertical through connection. Such an electrically conductive vertical through connection may particularly denote one or more vertically extending metallic structures, for example comprising or consisting of copper. Examples for an electrically conductive vertical through connection may be a metal pillar (in particular a copper pillar), a metal cylinder, a metal-filled drill hole (such as a plated laser via or a plated mechanically drilled via), an array of vertically stacked vias, or a stacked via-pad sequence. In one embodiment, all electrically conductive elements of the glass inlay, apart from the patterned metal layer thereon, may be vertical through connections. However, in an embodiment, the glass inlay may additionally comprise one or more horizontal electric connection elements. A corresponding horizontal electric connection element may be located at a surface of the glass inlay and/or in an interior of the glass inlay.

In an embodiment, a surface roughness Ra of the glass inlay is not more than 100 nm, in particular not more than 50 nm. The surface roughness Ra may be in particular present at a surface area of the glass inlay at which the patterned metal layer is formed. Such a low roughness Ra may ensure that the patterned metal layer may be formed on this surface of the glass inlay with highest spatial accuracy. Thus, the described embodiment may be particularly appropriate for high-density integration (HDI) applications and/or for fine line patterning.

In an embodiment, the carrier body comprises a further patterned metal layer at the same vertical level as the patterned metal layer on the glass inlay. For instance, pads of the carrier body and pads of the patterned metal layer may be at the same vertical level. Hence, coplanar patterned metal layers may be provided both at the glass inlay and at the carrier body. Said coplanar patterned metal layers may be electrically coupled with each other so that electric signals and/or electric power may be transmitted through the patterned metal layers on glass inlay and carrier body. While the patterned metal layer on the glass inlay may be electrically coupled with a higher density integration region of the package, the patterned metal layer of the carrier body may be electrically coupled with a lower density integration region of the package at its bottom side. Integration density of a package region may denote a number of electrically conductive structures per volume or area. In view of the excellent planarity of glass, the glass material meets even demanding requirements in terms of accuracy and is therefore compatible with high integration density requirements. When electrically coupling the carrier body with a lower integration density region, it can be manufactured with low effort, for instance as a PCB core.

In an embodiment, the glass inlay has a thickness in a range from 30 μm to 2000 μm. Hence, a thickness of the glass inlay can be in the same order of magnitude as a thickness of typical semiconductor chip-type electronic components which may be surface mounted on the package. This promotes a chip scale-like characteristic of the glass inlay.

In an embodiment, a size of the glass inlay in a horizontal plane is larger than or equal to a size of the electronic component in a horizontal plane. This ensures that the surface mounted electronic component can be located with its entire horizontal extension above the glass body. Consequently, the high spatial accuracy of the patterned metal layer on the glass body (thanks to the high planarity of glass) may translate to a high spatial accuracy of the electric interconnection of the surface mounted electronic above the glass inlay.

In an embodiment, a difference between a horizontal surface area of the glass inlay and a horizontal surface area of the electronic component divided by the horizontal surface area of the glass inlay is not more than 50%, in particular not more than 5%. To put it briefly, the glass inlay may be only slightly larger than the electronic component, if at all. Descriptively speaking, a surface area difference in a horizontal plane between the glass inlay and the electronic component, in relation to said surface area of the glass inlay, is not more than 50%, in particular not more than 5%. Thus, there may be only a small difference of the sizes of the glass inlay and of the electronic component. Descriptively speaking, this may lead at least approximately to a chip-scale glass configuration, i.e. a glass inlay scaled very similarly as a chip-type electronic component. Such an adaptation may result in advantageous properties in terms of warpage and delamination and may also contribute to an accurate electric interconnection of the surface mounted electronic component with respect to the patterned metal layer on the glass inlay.

In an embodiment, a difference between a height of the glass inlay and a height of the electronic component divided by the height of the glass inlay is less than 20%. Hence, a height difference between the glass inlay and the electronic component may be less than 20% or at least less than 30%. It may even be less than 10%. By also adjusting a glass inlay and an electronic component concerning thickness, the mechanical properties of the package can be further improved, in particular what concerns warpage and delamination.

In an embodiment, the package comprises a top-sided layer build-up vertically between the carrier body and the glass inlay on the one hand and the electronic component on the other hand. Preferably, such a layer build-up may be provided above both the carrier body and the glass inlay. The layer build-up may be embodied in form of a laminated layer stack. Such a laminated layer stack may be formed of one or more electrically insulating layer structures (such as prepreg sheets) and one or more electrically conductive layer structures (such as copper vias and/or patterned copper foils or layers). In the context of the present application, the term “stack” may particularly denote an arrangement of multiple planar layer structures which are mounted in parallel on top of one another. Furthermore, the term “layer structure” may particularly denote a continuous layer, a patterned layer or a plurality of non-consecutive islands within a common plane. The carrier body with one or more integrated glass inlays may form a robust mechanical base or support and may electrically connect to the top-sided laminated layer stack. The additional build-up may be a component carrier-type build-up, i.e. in particular constructed as a printed circuit board (PCB) or as an integrated circuit (IC) substrate. In particular, such an additional build-up may refine the electric interconnection of the surface mounted electronic component in particular with the carrier body.

In an embodiment, the top-sided layer build-up comprises a redistribution structure. In the context of the present application, the term “redistribution structure” may particularly denote a plurality of patterned electrically conductive layer structures in a dielectric matrix which have a portion with a smaller pitch as compared to another portion with a larger pitch. Pitch may denote a characteristic distance between adjacent electrically conductive structures, such as wiring elements or terminals. By providing spatially separate regions with different pitch, a redistribution structure may be an electric interface between larger dimensioned electric connection structures (in particular relating to component carrier technology, more particularly printed circuit board technology or integrated circuit substrate technology) and smaller dimensioned electric connection structures (in particular relating to semiconductor chip technology, wherein a connectable component may be a semiconductor chip). In particular, a number of electrically conductive structures per area or volume may be larger in a region with smaller pitch than in another region with larger pitch. A region with larger pitch may be arranged where the patterned metal layer on the glass inlay is located, whereas another region with smaller pitch may be arranged at a periphery or an outer region of the package where the electronic component is to be electrically connected. A function of the redistribution structure may be to rearrange the circuity and realize interconnection of two different densities of electric connection structures. For example, the redistribution structure may be a redistribution layer (RDL).

In an embodiment, the top-sided layer build-up comprises at least one horizontal power connection line for providing electrical power to the electronic component. Correspondingly, the carrier body may comprise a power connection structure comprising electrically conductive vertical connection elements and electrically conductive horizontal connection elements being interconnected for providing the connection with the electrical component in an area between said electrical component and the glass inlay. In particular, the at least one horizontal power connection line arranged inside of the top-sided layer build-up may extend horizontally from a position above the carrier body up to a position above the glass inlay and beneath the electronic component. Two coplanar horizontal power connection lines may be foreseen for enhanced symmetry and may be arranged at opposing side walls of the glass inlay. The described electric power supply configuration leads to relatively short electric paths and thus to low loss and an only limited heat transfer to an interior of the package during operation.

In an embodiment, the package has a bottom-sided layer build-up below the carrier body and the glass inlay. Also, on the bottom of the carrier body and the glass inlay, an additional layer build-up may be formed, for instance as a laminated layer stack comprising at least one electrically conductive layer structure and/or at least on electrically insulating layer structure.

In an embodiment, the bottom-sided layer build-up has regions of different thicknesses below the glass inlay and below the carrier body. By taking this measure, it may be possible to balance out thickness differences between a glass inlay and a carrier body at a bottom side thereof. For example, upper main surfaces of the glass inlay and the carrier body may be in alignment with each other, i.e. may be coplanar. In case of thickness differences between the glass inlay and the carrier body, lower main surfaces may be misaligned vertically. Advantageously, the bottom-sided layer build-up may balance such a bottom-sided misalignment by providing different thicknesses below the glass inlay and carrier body. Hence, with this configuration, even when the package is an asymmetric structure, the warpage issue will be mitigated. For instance, this can be accomplished by a dielectric filling medium (for instance with a low Young's modulus value preferably below 5 GPa in order to function as a soft buffer) below the glass inlay and carrier body, for instance glue or resin of a laminated dielectric sheet of the bottom-sided layer build-up.

In an embodiment, the top-sided layer build-up and the bottom-sided layer build-up are asymmetric, in particular have different thicknesses, in particular different maximum thicknesses. Advantageously, the top-sided build-up and the bottom-sided build-up do not necessarily have to be symmetric. In contrast to this, the top-sided build-up and the bottom-sided build-up may be asymmetric (for instance what concerns layer count, thickness, material, integration density). The high stability of the package thanks to the provision of the at least one glass inlay may make it possible that a construction of the package in a vertical direction shows a deviation from a symmetric configuration. As a result, a high integration density at a component mounting side of the package may be combined with a high freedom of designing the opposing main surface of the package without the risk of undesired phenomena such as warpage or delamination. Although the package may have an asymmetric structure, in particular a different layer count on the two opposing sides, the top side and the bottom side may have a compensation freedom concerning thickness with respect to each other. Advantageously, this may balance warpage. However, the thickness on the top side and on the bottom side may also be the same.

In an embodiment, the top-sided layer build-up (in particular a portion thereof corresponding to a lateral extension of a glass body and/or an electronic component) has a higher integration density than the bottom-sided layer build-up. The term “integration density” may denote a number of electrically conductive structures per area or volume of the respective region of the package. In particular, the amount of contacts (including pads) per area or volume on the redistribution structure of the top-sided build-up may be higher than the amount of the contacts (including pads) per area or volume on the bottom-sided build-up which may face a mounting base such as a PCB. Thus, integration density may mean a quantity of electrically conductive structures (such as traces) per mm². The integration density below a glass inlay and carrier body can be smaller than in the redistribution structure above the glass inlay and carrier body, and correspondingly the line space ratios may be different. Since PCB and IC substrate technology may be based on larger electrically conductive structures than semiconductor technology (according to which a component connected with the redistribution structure may be formed), the mentioned design rule may be appropriate for bridging the two combined technologies. The side of the package relating to the redistribution structure may provide a mounting area for mounting one or a plurality of electronic components such as semiconductor chips and can thus be provided advantageously with a high integration density. At the same time, the side of the package relating to the bottom-sided layer build-up may be configured for connecting the package at the surface with a mounting base, such as a printed circuit board.

In an embodiment, the electronic component comprises a semiconductor chip. The semiconductor chip may be made for instance based on a type IV semiconductor such as silicon or germanium, or may be a type III-V semiconductor material such as gallium arsenide. In particular, the semiconductor component may be a semiconductor chip such as a bare die or a molded die. A bare die may be a non-encapsulated (in particular non-molded) piece of semiconductor material (such as silicon) having at least one monolithically integrated circuit element (such as a diode or a transistor). Moreover, semiconductor materials suitable for photonic packages are also possible. For example, an electronic component to be surface mounted on the package may be an HBM (high-bandwidth memory) or a silicon interposer.

In an embodiment, the only metallic material covering the glass inlay is the patterned metal layer on the glass inlay. More specifically, there may be only one patterned metal layer on the glass inlay, in particular on an upper main surface thereof. All other surface areas of the glass inlay may be free of metallic material and may be in contact with dielectric material only. Such a design simplifies manufacture of the glass inlay with the patterned metal layer thereon but without other metallic constituents. The electric paths of the package, in particular what concerns electric energy supply and electric signal transmission, may extend below the glass inlay only laterally thereof (but not directly below the glass inlay) may then bypass the glass inlay laterally and may extend both laterally and directly above the glass inlay up to the electronic component (see FIG. 1). Such a design allows a simple construction of the glass inlay and is in line with smaller pitch requirements on the side of the electronic component and larger pitches on an opposing side of the package which may face a mounting base.

In an embodiment, the electronic component is laterally misaligned with respect to the glass inlay so as to be arranged partially above the carrier body (for instance central symmetry axes of electronic component and glass inlay may be mutually displaced). With correspondingly relaxed requirements concerning alignment accuracy between the glass inlay and electronic component, an easier connection of the electronic component to the (in particular core-type) carrier body may be achieved. Alternatively, the electronic component may be laterally aligned with the glass inlay (for instance central symmetry axes of electronic component and glass inlay may coincide).

In an embodiment, the package comprises a further electronic component mounted above the glass inlay. Thus, two or more electronic components may be assigned to a common glass inlay embedded in the carrier body. Preferably, the sum of the lateral dimension of the two or more electronic components being surface mounted side-by-side may correspond or may correspond substantially to the lateral extension of the glass inlay.

For example, the electronic component and the further electronic component may functionally cooperate, for instance may exchange electric signals. In one embodiment, the electronic component is a processor, and the further electronic component is a memory chip. In another embodiment, the electronic component is a control chip, and the further electronic component is a sensor chip controlled by the control chip. In still another embodiment, the electronic component is an optical chip, and the further electronic component is an assigned electric chip. Other combinations of electronic components are, however, possible. The electronic component can be an RFIC (radio-frequency integrated circuit), and/or a chiplet for heterogeneous packaging.

Many different configurations are possible concerning the number of electronic components and the number of glass inlays: In one embodiment, a single electronic component is mounted above a single glass inlay. In another embodiment, a plurality of electronic components is mounted above a common glass inlay. In still another embodiment, an electronic component is mounted above a plurality of glass inlays. In yet another embodiment, a plurality of electronic components (in particular chips or chiplets) are mounted above a plurality of glass inlays. A plurality of glass inlays may be embedded in different cavities (such as through holes) of a common carrier body.

In an embodiment, the patterned metal layer is configured to function as a bridge between the electronic component and the further electronic component. By configuring the patterned metal layer so as to provide a bridge function and so as to electrically couple the surface mounted electronic component and the further electronic component with each other, the handling of separate component connecting members (such as bridge dies or interposer inlays) may be dispensable.

The component can also be a chiplet (such as a plurality of small chips with different modules combined as one big chip to function, for example, a central processing unit (CPU) or a graphical processing unit (GPU). The chiplet can be placed on the same surface or it can be stacked with each other as a three-dimensional package.

In an embodiment, the patterned metal layer is formed in a design layer structure having a stamped surface profile. In particular, the patterned metal layer may be a NIL (Nanoimprint Lithography) patterned structure. Concerning a NIL-type patterned metal layer, more generally a patterned metal layer formed in a design layer with stamped surface profile, metal in indentations of said stamped surface profile may be provided. In the context of the present application, the term “design layer” may denote a layer being flexibly processable for designing substantially any desired surface profile extending therein and/or therethrough. Thus, any desired wiring design may be translated into a corresponding surface profile of the design layer so that filling created indentations in the design layer with electrically conductive material may lead to the predefined wiring design. Preferably, the design layer may be an initially at least partially uncured dielectric which may be cured during and/or after stamping a predefined surface profile therein. The surface profile may then be rendered permanent. Hence, the design layer may be deformable before curing and may be non-deformable after curing. Preferably, one or more indentations in the design layer structure may have different horizontal and/or vertical extensions. Alternatively, they may be the same. In the context of the present application, the term “stamping a surface profile in the design layer” may denote the process of imprinting or embossing a predefined surface pattern in the design layer. For instance, this may be accomplished by pressing a working mold (or working stamp) in the (in particular still) deformable design layer or by guiding a working mold along the (in particular still) deformable design layer. Such a working mold may have an inverse surface profile in comparison with the surface profile of the design layer being processed. During a development and manufacturing process, first a master mold may be manufactured, for example, by gray scale lithography. Then the master mold may be replicated by stamping several times into a transparent silicone material or the like, and a master working mold may be generated. Finally, working molds may be made by copying the master working mold. The working molds may be used during mass production and imprinted on the panel surface. In the context of the present application, the term “stamped surface profile” may denote a surface profile having a characteristic structure resulting from a stamping process executed by pressing a work mold into the design layer. In view of this manufacturing process, the stamped surface profile has a lower roughness, steeper sidewalls and other pattern characteristics than obtainable by etching-based or laser-based patterning processes.

In an embodiment, the patterned metal layer is formed on a main surface of the glass inlay facing the electronic component, i.e. an upper main surface. Such a geometry may keep the electric paths (what concerns electric power supply and/or propagation of electric signals) short. This may lead to small ohmic losses and high signal integrity.

In an embodiment, the carrier body has a further cavity. The package may comprise a further glass inlay embedded in the further cavity of the carrier body. In such an embodiment, a redistribution structure may be formed partially above the glass inlay and partially above the further glass inlay. In such an embodiment, at least two glass inlays in combination with a common carrier body may share a preferably continuous redistribution structure. Hence, even sophisticated electronic functionality may be realized with such a design.

In an embodiment, an exterior interface area of the package facing away from the electronic component may be configured as a grid array interface, for instance as a ball grid array interface or a land grid array interface. Land Grid Array (LGA) and Ball Grid Gray (BGA) are both Surface Mount Technologies (SMT), in particular for printed circuit boards or motherboards. They basically define how the package will actually be mounted, in particular on a PCB or a motherboard's socket. Essentially, the most basic difference between the two is that an LGA based package can be plugged in and out of the PCB or motherboard and can also be replaced. A BGA based package, however, may be soldered on the PCB or motherboard and thus cannot be plugged out or replaced. A Ball Grid Array, on the other hand, may have spherical contacts which are then soldered onto the PCB or motherboard. An LGA type package may be placed on top of a socket on a PCB or motherboard. In this context, the package may have flat surface contacts whereas the PCB or motherboard socket may have pins.

In an embodiment, at least one of the carrier body, the top-sided build-up, and the bottom-sided build-up may be embodied as a component carrier (such as a PCB or an IC substrate) or as a component carrier stack.

In an embodiment, the component carrier is shaped as a plate. This contributes to the compact design, wherein the component carrier nevertheless provides a large basis for mounting components thereon. Furthermore, in particular a naked die as an example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole as dielectric layer. It is also possible that the substrate or interposer comprises a metallic structure as electrically conductive layer.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one component may be embedded in and/or surface mounted on the package. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics such as for instance copper, aluminum oxide (Al₂O₃) or aluminum nitride (AIN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light-mitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

The aspects defined above, and further aspects of the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a package according to an embodiment of the disclosure.

FIG. 2, FIG. 3, FIG. 4, FIG. 5, FIG. 6, and FIG. 7 respectively illustrate cross-sectional views of structures obtained during carrying out a method of manufacturing a package, shown in FIG. 7, according to embodiments of the disclosure.

FIG. 8 illustrates a preform of a package according to an embodiment of the disclosure.

FIG. 9 illustrates a cross-sectional view of a package according to another embodiment of the disclosure.

### DETAILED DESCRIPTION OF THE ILLUSTRATED EMBODIMENTS

The illustrations in the drawings are schematically presented. In different drawings, similar or identical elements are provided with the same reference signs.

Before, referring to the drawings, example embodiments will be described in further detail, some basic considerations will be summarized based on which embodiments of the disclosure have been developed.

Fan-out wafer level packaging may allow a significant miniaturization concerning volume but also thickness. At a technological core of such a package may be the formation of a reconfigured molded wafer combined with a thin-film redistribution structure to yield a surface mounted device compatible package. Main advantages of a fan-out wafer level packaging are the provision of a substrate-less package, a low thermal resistance, an improved RF (radio-frequency) performance due to shorter interconnects together with direct IC connection by thin-film metallization instead of wire bonds or flip chip bumps and lower parasitic effects to provide a good signal integrity. Fan-out wafer-level packaging can be used in particular for multi-chip packages, for system-in-package (SiP) and for heterogeneous integration. For higher productivity and resulting lower manufacturing effort larger mold embedding form factors may be considered. Besides increasing wafer diameter, a further option is moving to panel sizes leading to fan-out panel level packaging.

Example embodiments of the disclosure may relate to a package providing an even more stable chip packaging substrate with chip scale patterned glass and a high-density build-up on top to connect with one or more electronic components such as chips. This may allow to provide a package which can be manufactured by chip last fan-out panel-level or wafer-level packaging.

According to an example embodiment of the disclosure, a package with a carrier body (in particular a component carrier core) and at least one glass inlay embedded therein may be provided. Advantageously, a patterned metal layer (such as a copper trace) can be formed (preferably directly) on a main surface of the glass inlay. At least one electronic component (such as a semiconductor chip) may be mounted above the glass inlay, and preferably electrically connected with the patterned metal layer.

It may also be possible that a redistribution layer is formed directly on the glass inlay and extends horizontally to the component carrier surface. However, there can be also a same level connection between the glass inlay and the component carrier.

Such a packaging architecture has advantages: Firstly, such a design may enable glass scale packaging using a fan-out substrate. Furthermore, such a package may benefit from a low CTE chip scale patterned glass inlay embedded in a core-type carrier body which may allow to improve the chip packaging performance. Beyond this, such a packaging architecture is properly compatible with a chip last manufacture, which may lead to a high yield and low manufacturing effort. Packages according to an embodiment of the disclosure may benefit from a high assembly performance with small or even no scale variance on a chip bonding area. Furthermore, a proper signal integrity may be achieved, in particular for high-speed signals, due to the patterned metal layer on the glass body of the glass inlay. This may be achieved since the glass surface is smooth with low roughness and the signal loss is also less than with organic material.

In an embodiment, a package according to an embodiment of the disclosure may be manufactured in fan-out wafer-level packaging architecture.

Furthermore, a package according to an embodiment of the disclosure may be configured as a fan-out panel-level package (FOPLP). Descriptively speaking, the package may be manufactured on a panel level and may comprise a fan-out and/or redistribution structure functionality, which adds the value of efficiency and economies of scale and provides an advanced package solution with high density. In addition to the production cost advantage, it also comprises the performance advantage on products due to its applicable architectural structure on fine line structure for improving the electrical and thermal performance. It is suitable for both the Fan-out SiP and Heterogeneous Integration. For instance, such a package may not only be highly appropriate for mobile phone applications and related electronic devices but also for applications of 5G, AI autonomous driving and server. Such a fan-out panel-level package may be manufactured with high yield. This may result from improved packaging conditions with high stiffness and a chip last packaging architecture, i.e. an assembly of a chip-type electronic component at the end of the manufacturing process.

Advantageously, a package architecture is provided which allows manufacture with low effort by embedding a chip-scale metal patterned glass inlay in a (for example core-type) carrier body. Advantageously, no through glass via (TGV) is necessary for such a package design which therefore allows a high processing efficiency and less manufacturing cost and effort.

To put it briefly, a package according to a preferred embodiment of the disclosure may provide a chip-scale patterned glass inlay embedded in a core-type carrier body. In particular, a chip-scale patterned glass inlay may be a glass inlay with patterned metal layer, wherein a lateral extension of the glass inlay or its patterned metal layer may correspond to an extension of a chip-type electronic component mounted at a top side of the package. A corresponding package may improve the chip packaging performance in a chip last fan-out configuration. By mounting the chip-type electronic component only at the end of the manufacturing process, a high yield may be obtained. By forming a redistribution structure vertically and horizontally between the electronic component and a glass inlay, a fan-out configuration may be realized. A package according to an embodiment may also allow a proper assembly performance with low-scale variance of chip bonding area. Furthermore, a good signal integrity may be achieved thanks to the patterned metal layer on the highly flat glass inlay. Moreover, the high stiffness of the glass inlay may ensure a proper mechanical integrity and therefore reliable packaging conditions. Due to a central support structure composed of a core-type carrier body with embedded glass inlay may provide stability for forming an asymmetric build-up on both opposing main surfaces thereof.

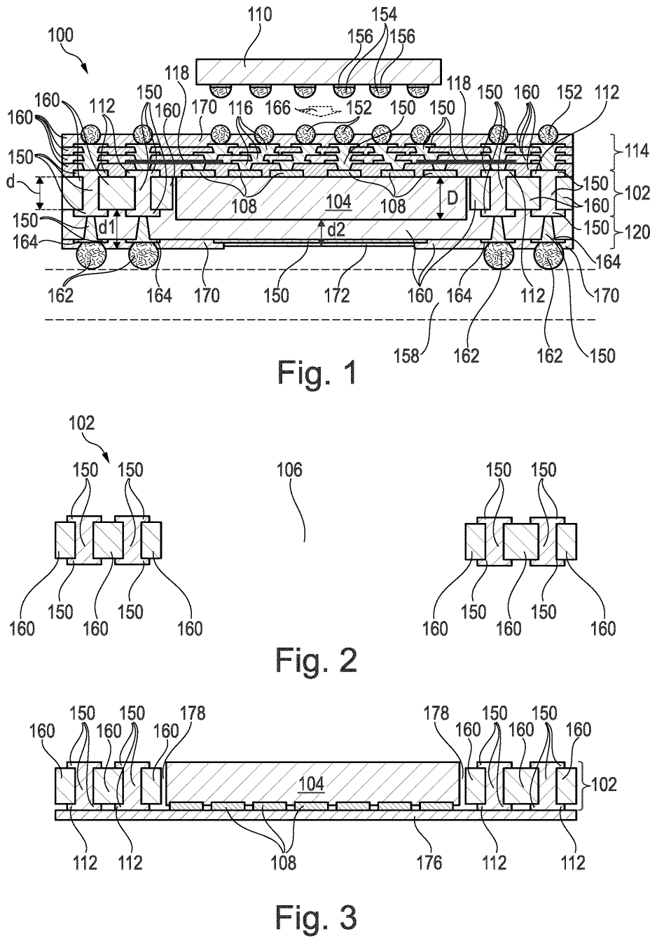

FIG. 1 illustrates a cross-sectional view of a package 100 according to an embodiment of the disclosure.

As shown in FIG. 1, an electronic component 110 is surface mounted on the package 100. However, it is alternatively also possible that a plurality of electronic components (see reference signs 110, 122 in FIG. 7) may be surface mounted on an upper main surface of the package 100 (not shown in FIG. 1). In particular, the illustrated electronic component 110 may be a semiconductor chip, for example for high-frequency applications. As shown, the electronic component 110 may have a large number of input/output (I/O) pads 156.

As shown as well, the top side of the package 100 comprises electrically conductive connection structures 152, such as solder balls (or alternatively metal bumps or other metallic interconnect structures). Additionally or alternatively, the bottom side of the electronic component 110 may comprise electrically conductive connection structures 154 on the pads 156 at a bottom of the semiconductor body of the electronic component 110. By said electrically conductive connection structures 152 and/or 154, the electronic component 110 may be electrically and mechanically connected to the package 100, for instance by soldering (or by sintering) or any other kind of bonding structuring (such as wiring bonding, hybrid bonding, etc.). A corresponding assembly and connection process is indicated by an arrow 166 in FIG. 1.

On a bottom side of the package 100, a mounting base 158 can be provided on which the package 100 is mounted while establishing an electric connection in between. This may be accomplished by electrically conductive connection structures 162 between package 100 and mounting base 158, for instance solder balls or sinter structures. The bottom side of the package 100 may be provided with an electrically conductive pattern depending on a specific application. In the shown embodiment, a plurality of metallic (in particular copper) pads 164 are foreseen at the bottom main surface of the package 100 which may be electrically connected to the mounting base 158 by the electrically conductive connection structures 162. Additionally or alternatively, metal pillars (in particular copper pillars) may be provided as electrically conductive pattern on the lower main surface of the package 100 (not shown).

For example, the mounting base 158 may be a printed circuit board (PCB) or an interposer. Although not shown in FIG. 1, further components (such as IC substrates, further (in particular molded) semiconductor chips, etc.) may be assembled on the mounting base 158. The mounting base 158 can also be omitted in other embodiments.

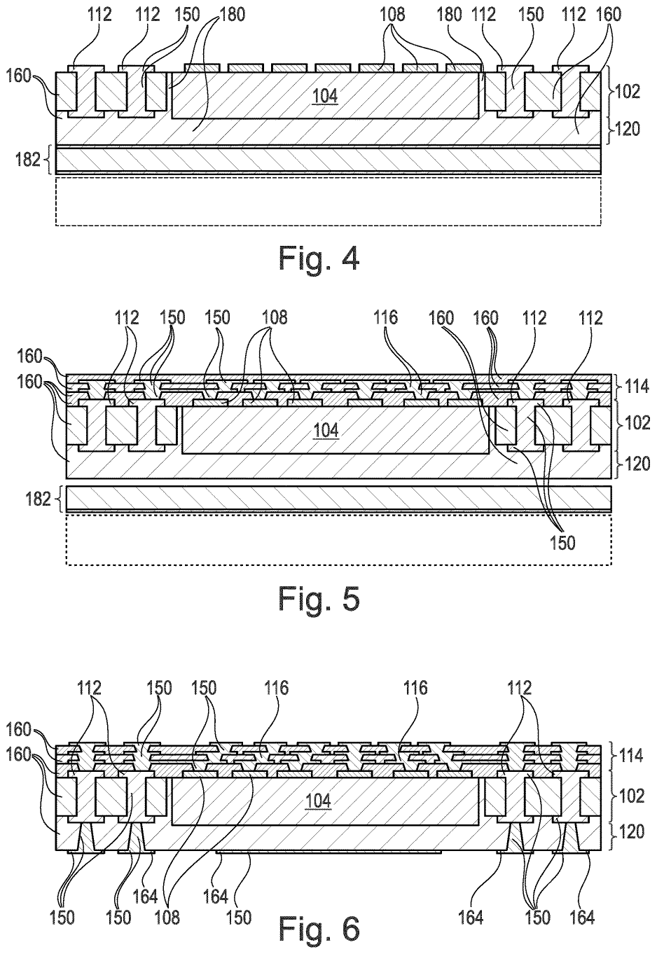

Package 100 according to FIG. 1 comprises a carrier body 102 having a cavity 106 (see FIG. 2). A glass inlay 104 is embedded in the cavity 106 of the carrier body 102. A patterned metal layer 108, which may for instance be a structured copper foil or a deposited copper layer, is formed exclusively on an upper main surface of the glass inlay 104. More specifically, the patterned metal layer 108 is formed on a main surface of the glass inlay 104 facing the electronic component 110 in a surface mounted configuration. This geometry leads to short electric connection paths from or to the electronic component 110 and therefore to low losses and high signal integrity. When interconnected within package 100, the patterned metal layer 108 may for example function for impedance control.

According to FIG. 1, the carrier body 102 is embodied as an organic core, preferably manufactured in printed circuit board technology. For instance, said core may be made of fully cured resin with reinforcing particles, such as glass spheres, therein. For example, the carrier body 102 may comprise or consist of a laminated layer stack comprising a plurality of electrically conductive layer structures 150 and electrically insulating layer structures 160. The electrically conductive layer structures 150 may comprise patterned copper layers which may form horizontal pads and/or a horizontal wiring structure. Additionally or alternatively, the electrically conductive layer structures 150 may comprise vertical through connections such as copper pillars and/or copper filled laser vias. Moreover, the stack of the carrier body 102 may comprise one or more electrically insulating layer structures 160 (such as prepreg or resin sheets). On its upper main surface, the carrier body 102 comprises a further patterned metal layer 112 which is preferably located at the same vertical level as the patterned metal layer 108 on the glass inlay 104. In other words, the further patterned metal layer 112 and the patterned metal layer 108 may be coplanar which may simplify formation of a mutual electrically conductive interconnection in between. Advantageously, the described core-type carrier body 102 may be manufactured with low effort.

As already mentioned, the glass inlay 104 is embedded in the cavity 106 of the carrier body 102. The glass inlay 104 may be a glass body (for example made of silicon-based glass) with the patterned metal layer 108 on top of the glass body. Such a glass inlay 104 may be free of electrically conductive vertical through connections, such as through glass vias. Thus, the only metallic material covering the glass inlay 104 may be the patterned metal layer 108. This significantly simplifies the manufacturing process without compromising on proper electric connectivity. Glass is a highly appropriate material for the inlay 104, since this material is very robust against temperature changes. This may stabilize the whole package 100 with less dimension change during manufacturing in the different environmental conditions. Moreover, glass provides a high mechanical strength and is therefore very suitable for providing mechanical stability to the package 100 as a whole. Beyond this, the glass inlay 104 can be provided with a very smooth surface having a very small roughness Ra for example less than 100 nm. This may provide a good performance for electricity transmission with less signal loss. In particular at an upper horizontal main surface of the glass inlay 104, a high degree of flatness may be achieved which may promote formation of the patterned metal layer 108 on (and preferably directly on) the glass inlay 104 with high spatial accuracy and good structural uniformity. In other words, the flat surface of the glass inlay 104 is fully compatible with fine line structuring of the patterned metal layer 108 on top thereof. For example, the glass inlay 104 has a thickness D in a range from 30 μm to 2000 μm, for example 100 μm. A thickness d of the carrier body 102 may be in the same order of magnitude as the thickness D of the glass inlay 104, for example the thickness may be slightly smaller.

The above-mentioned electronic component 110 is surface mounted on the package 100 and is mounted above and in lateral alignment with the glass inlay 104. As shown, a size of the glass inlay 104 in a horizontal plane is only slightly larger than a size of the electronic component 110 in a horizontal plane. For example, a surface area difference in a horizontal plane between the glass inlay 104 and the electronic component 110 is not more than 10%. More precisely, this means that a difference between the surface area of the upper main surface of the glass inlay 104 and the surface area of the upper main surface of the electronic component 110 divided by the surface area of the upper main surface of the glass inlay 104 is not more than 10%. This calculation rule can also be applied when the percentage is different, for instance not more than 5% or not more than 20%. Thus, the glass inlay 104 may be configured as a patterned chip-scale glass body rather than extending substantially over the entire lateral extension of the package 100. This may allow arrangement of glass only below the electronic component 110 and thus where functionally advantageous, whereas other lateral sections of the vertically central support structure may be provided by a low-cost core-type carrier body 102. Furthermore, this may provide a shorter signal path between the glass inlay 104 and the component 110.

Furthermore, a height difference between the glass inlay 104 and the electronic component 110 may be less than 20%. More precisely, this means that a difference between the height of the glass inlay 104 and the height of the electronic component 110 divided by the height of the glass inlay 104 is not more than 20%. This calculation rule can also be applied when the percentage is different. Also, a height adaptation between glass inlay 104 and electronic component 110 may contribute to advantageous properties of the package 100. Furthermore, this may balance the stress of the package 100 on the top side and the bottom side for better warpage control.

Adapting dimensions of glass inlay 104 and electronic component 110 may be advantageous concerning warpage management and suppression of delamination. In particular appropriate may be a configuration in which the glass inlay 104 is formed based on silicon-based glass and the electronic component 110 is a silicon chip. This material combination of silicon-based bodies 104, 110 has advantages: On the one hand, the CTE value of silicon is relatively low so that the package 100 as a whole does not suffer from excessive thermal expansion of glass inlay 104 and electronic component 110. On the other hand, forming both the glass inlay 104 and the electronic component 110 based on silicon also keeps the CTE mismatch between silicon-based bodies 104, 110 small. Consequently, a package 100 with high thermal reliability may be obtained.

In the package 100, the electronic component 110 may also be laterally misaligned with respect to the glass inlay 104 so that the electronic component 110 is arranged partially above the carrier body 102. Thus, the package architecture is not sensitive with respect to a certain misalignment between electronic component 110 and glass inlay 104. This relaxes the manufacturing process and allows also certain tolerances. Alternatively, the electronic component 110 may be laterally aligned with respect to the glass inlay 104.

Furthermore, this may also provide a larger mounting surface for different components 110 (such as multiple components 110 mounted on the surface of the package 100). Moreover, the patterned glass inlay 104 with fine line structuring can function as a bridge to interconnect the different components 110. This may reduce the RDL layer count or may allow to omit an interposer. Consequently, there may be less manufacturing effort for producing the substrate and less cost compared with a conventional package using more large-scale silicon.

As shown as well in FIG. 1, a top-sided layer build-up 114 is vertically interposed between the carrier body 102 and the glass inlay 104 at a bottom side and the electronic component 110 at a top side. As shown, the layer build-up 114 comprises a laminated layer stack comprising a plurality of electrically conductive layer structures 150 and electrically insulating layer structures 160. The electrically conductive layer structures 150 may comprise patterned copper layers which may form horizontal pads and/or a horizontal wiring structure. Additionally or alternatively, the electrically conductive layer structures 150 may comprise vertical through connections such as copper pillars and/or copper filled laser vias. Moreover, the stack of the layer build-up 114 may comprise one or more electrically insulating layer structures 160 (such as prepreg or resin sheets).

Advantageously, the top-sided layer build-up 114 illustrated in FIG. 1 comprises a redistribution structure 116. The illustrated redistribution structure 116 of the package 100 is formed on the glass inlay 104 and is electrically coupled with the patterned metal layer 108.

The redistribution structure 116 translates between a smaller pitch at its top main surface, i.e., at an interface to the surface mounted component 110, and a larger pitch at its bottom main surface to which the patterned metal layer 108 on the glass inlay 104 and optionally also the carrier body 102 is or are electrically connected. Descriptively speaking, the upper main surface of the redistribution structure 116 has a pitch or a line space ratio corresponding to the demands of semiconductor technology which allows to connect semiconductor chip-type component 110 with the exposed main surface of the redistribution structure 116. Furthermore, the lower main surface of the redistribution structure 116 has another (i.e. larger) pitch or line space ratio corresponding to the requirements of printed circuit board technology which allows connection of mounting base 158 with the exposed lower main surface of the package 100. To put it briefly, the redistribution structure 116 translates between smaller characteristic dimensions of semiconductor technology and larger characteristic dimensions of PCB technology.

Still referring to FIG. 1, the top-sided layer build-up 114 comprises two horizontal power connection lines 118 each connected for providing electrical power to the electronic component 110. Such electric power may be supplied through electrically conductive layer structures 150 of a below described bottom-sided layer build-up 120, through electrically conductive layer structures 150 of carrier body 102 and electrically conductive layer structures 150 of the top-sided layer build-up 114 to the horizontal power connection lines 118 and from there upwardly up to the electronic component 110. Also, electric signals may be exchanged between the bottom side of the package 100 and the surface mounted electronic component 110 through electrically conductive layer structures 150 of the bottom-sided layer build-up 120, of the carrier body 102 and of the top-sided layer build-up 114.

Although not shown in FIG. 1, there may be optionally also a through glass via (TGV) extending vertically or slanted through the glass inlay 104.

The already mentioned bottom-sided layer build-up 120 is arranged below the carrier body 102 and below the glass inlay 104 and is directly connected to both. As shown, the bottom-sided layer build-up 120 comprises a laminated layer stack comprising a plurality of electrically conductive layer structures 150 and electrically insulating layer structures 160. The electrically conductive layer structures 150 may comprise patterned copper layers which may form horizontal pads and/or a horizontal wiring structure. Additionally or alternatively, the electrically conductive layer structures 150 may comprise vertical through connections such as copper pillars and/or copper filled laser vias. Moreover, the stack of the bottom-sided layer build-up 120 may comprise one or more electrically insulating layer structures 160 (such as prepreg or resin sheets). A vertical thickness or thickness distribution of the electrically insulating layer structure 160 of the bottom-sided layer build-up 120 may be adjusted to reduce warpage of package 100 by balancing the asymmetry of the structure. As shown as well, the bottom-sided layer build-up 120 has regions of different thicknesses d1, d2 below the glass inlay 104 and below the carrier body 102. In the embodiment shown, the thickness d1 of the bottom-sided layer build-up 120 below the carrier body 102 may be larger than the thickness d2 of the bottom-sided layer build-up 120 below the glass inlay 104. While the upper main surfaces of the carrier body 102 and of the glass inlay 104 are aligned with each other according to FIG. 1, there may be a vertical misalignment at the lower main surfaces of the carrier body 102 and the glass inlay 104 when they have a different thickness. Such a misalignment may be compensated by the varying thickness of the bottom-sided layer build-up 120.

It may also be possible to have the same level connected between the glass inlay 104 and the stack even in the presence of only one patterned layer.

As can be taken from FIG. 1, the top-sided layer build-up 114 with its redistribution structure 116 has a higher integration density than the bottom-sided layer build-up 120 accomplishing an interconnection with PCB-type mounting base 158. The number of electrically conductive elements of the electrically conductive layer structures 150 per volume or area is thus larger in the higher density connection region of the top-sided layer build-up 114 as compared with the lower density connection region of the bottom-sided layer build-up 120. This configuration supports the functionality of the redistribution structure 116. For example, the redistribution structure 116 may provide a line/space ratio below 5 μm/5 μm. In contrast to this, the bottom-sided layer build-up 120 may support a line/space ratio above 5 μm/5 μm.

As described and illustrated, the top-sided layer build-up 114 and the bottom-sided layer build-up 120 are asymmetric, in particular have different thicknesses, construction and materials. This asymmetric design is a consequence of the above-described different functionality of the build-ups 114, 120. However, this asymmetric configuration of the entire build-up of the package 100 does not lead to excessive warpage, delamination or other undesired artifacts, since the carrier body 102 with inserted glass inlay 104 provides a high degree of mechanical stability, lower CTE value and may be properly resistant to temperature change. To put it shortly, less defects may occur. Furthermore, the design of package 100 according to FIG. 1 provides sufficient degrees of freedom for adapting the configuration to achieve desired characteristics of the package 100. In particular, the thickness distribution of the electrically insulating layer structure 160 of the bottom-sided layer build-up 120 is such a design parameter which can be adjusted for warpage management.

Apart from the already described constituents, package 100 additionally comprises on both opposing main surfaces a solder resist 170 and on the lower main surface a surface finish 172 (like ENIG or ENEPIG). The surface finish 172 may protect exposed electrically conductive layer structures 150 and may promote solderability. The solder resist 170 may be a thin lacquer-like layer, for instance of polymer, that may be applied to electrically conductive layer structures 150 for protection against oxidation and to prevent solder bridges from forming between closely spaced solder pads.

FIG. 2 to FIG. 7 illustrate cross-sectional views of structures obtained during carrying out a method of manufacturing a package 100, shown in FIG. 7, according to an embodiment of the disclosure.

Referring to FIG. 2, a carrier body 102, preferably a PCB-type core, is shown in which a through hole-type cavity 106 is formed. Cavity 106 can be created, for example, by mechanically cutting or laser cutting.

Referring to FIG. 3, the through hole formed in the cut carrier body 102 may then be closed at a bottom side by attaching a temporary carrier 176 to the carrier body 102, for instance a tape.

Thereafter, a pre-manufactured glass inlay 104 with already formed patterned metal layer 108 on a bottom main surface of the inserted glass inlay 104 may then be inserted in cavity 106 and may also be attached to the temporary carrier 176. Gaps 178 remain between facing side walls of the glass inlay 104 and of the carrier body 102. The glass inlay 104 may be configured as patterned chip scale glass body, i.e. as partially metallized glass body of a size comparable with a size of electronic components 110, 122 being surface mounted later (see FIG. 7).

Referring to FIG. 4, the carrier body 102 and the glass inlay 104 may then be connected with each other by a dielectric filling medium 180 inserted into the gaps 178 and on top of the structure shown in FIG. 3. For instance, the dielectric filling medium 180 may be glue or may be resin of a dielectric laminate or paste. The portion of the dielectric filling medium 180 on top of the structure shown in FIG. 3 may later form an electrically insulating layer structure 160 of bottom-sided layer build-up 120.

After applying and curing the dielectric filling medium 180, the temporary carrier 176 may be removed, for instance by detaching a tape. The obtained structure may be flipped over, i.e. may be turned upside down.

The obtained structure may then be mounted on a further temporary carrier 182, such as a detachable copper foil (DCF).

Referring to FIG. 5, top-sided layer build-up 114 comprising redistribution structure 116 is then formed on the carrier body 102 and on the inserted glass inlay 104 by laminating and patterning further layer structures 150, 160 on the upper main surface of FIG. 4.

Thereafter, the further temporary carrier 182 may be detached. Copper material may then be etched away from the bottom main surface of the preform of the package 100.

Referring to FIG. 6, further electrically conductive layer structures 150 may be formed in the bottom-sided electrically insulating layer structure 160. In this context, pads 164 may be formed on the bottom main surface of the pre-form of the package 100 according to FIG. 6.

Referring to FIG. 7, a back-end process is illustrated. In this context, a dielectric solder resist 170 is formed on both opposing main surfaces of the structure according to FIG. 6 and can then be patterned so as to selectively expose specific surface portions of the electrically conductive layer structures 150 both on the upper main surface and the lower main surface of the structure according to FIG. 6. Electrically conductive connection structures 152, 162, in particular solder bumps, may be formed on selected exposed surface portions of the respective electrically conductive layer structures 150. For forming the electrically conductive connection structures 152, 162, it may also be possible to provide one or more copper posts, tin-silver structures, copper-tin structures, and/or nano teeth for interconnection. A metallic surface finish 172 may be formed on an exposed surface of an electrically conductive layer structure 150 at the bottom side.

Thereafter, an electronic component 110 and a further electronic component 122 are surface mounted above the glass inlay 104 and on the top-sided build-up 114, more specifically electrically coupled with the redistribution structure 116 thereof. As shown, the electronic components 110, 122 assembled side-by-side on the upper main surface of the package 100 have together a lateral width w which substantially corresponds to a lateral width W of the glass inlay 104.

In the configuration shown, the patterned metal layer 108 in collaboration with the redistribution structure 116 is configured to function as a bridge between the electronic component 110 and the further electronic component 122. Advantageously, the electronic component 110 and the further electronic component 122 may be mounted on the top-sided build-up 114 and on the connected patterned metal layer 108 in such a way that the latter function as a bridge between the electronic component 110 and the further electronic component 122 and electrically couple both with each other.

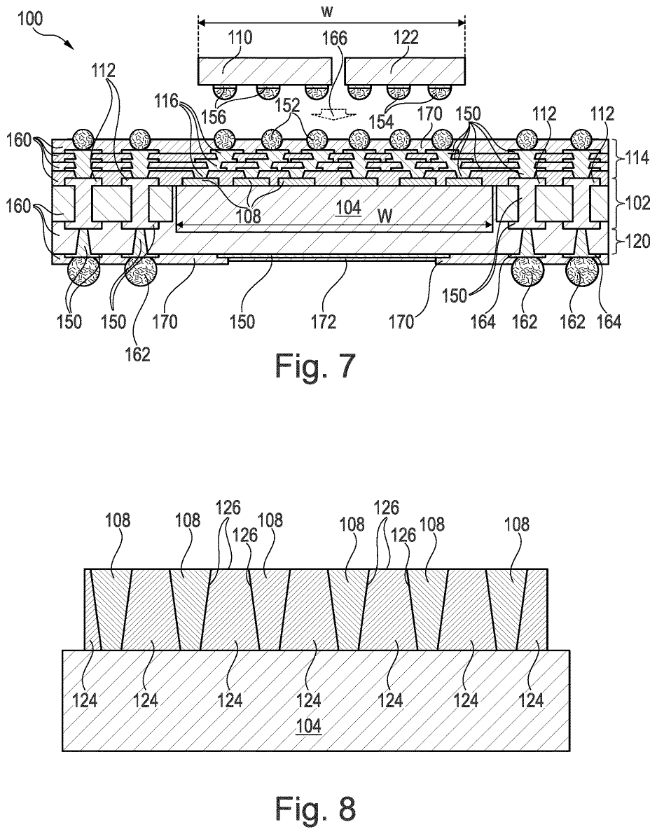

FIG. 8 illustrates a preform of a package 100 according to an exemplary embodiment of the disclosure. FIG. 8 shows the patterned metal layer 108 being formed in a design layer structure 124 having a stamped surface profile 126. While the patterned metal layer 108 of the embodiments of FIG. 1 to FIG. 7 can be an array of coplanar flat pads, the patterned metal layer 108 of FIG. 8 is formed of coplanar tapering metallic elements (which may have a significantly larger aspect ratio, i.e. thickness to diameter ratio, than the flat pads)

In order to obtain the structure according to FIG. 8, material for the design layer structure 124 may be dispensed on the glass inlay 104. For example, a thickness of the design layer structure 124 may be in a range from 0.1 μm to 25 μm. Hence, this may make it possible to create a very thin build-up. Advantageously, the design layer structure 124 may be configured as Nanoimprint Lithography (NIL) layer. After dispensing, the design layer structure 124 may still be at least partially uncured, i.e. may be in particular still capable of cross-linking or polymerizing.

Thereafter, the design layer structure 124 may be stamped on the glass inlay 104 by a profiled working mold (not shown) so that a predefined surface profile of the stamped design layer structure 124 is formed. Thus, the illustrated surface profile may be stamped in the design layer structure 124. For this purpose, a working mold may be pressed into the still deformable design layer structure 124 so that a surface profile of the working mold is transferred into an inverse surface profile imprinted in the design layer structure 124. Descriptively speaking, the created surface profile in the design layer structure 124 corresponds to an electrically conductive pattern to be formed. In the shown embodiment, formation of a surface profile in the design layer structure 124 may create a plurality of indentations. As can be taken from FIG. 8 as well, the indentations formed in the design layer structure 124 taper inwardly. This is the result of a corresponding tapering shape of protrusions of the working mold creating the indentations in the design layer structure 124. Advantageously, the design layer structure 124 may be cured simultaneously during the process of stamping, for instance by ultraviolet light.

Thereafter, the patterned metal layer 108 is formed by filling the indentations with metallic material, in particular copper. For example, this can be accomplished by a combination of an electroless plating process (such as sputtering or a chemical process) and an electroplating process (for example galvanic plating).

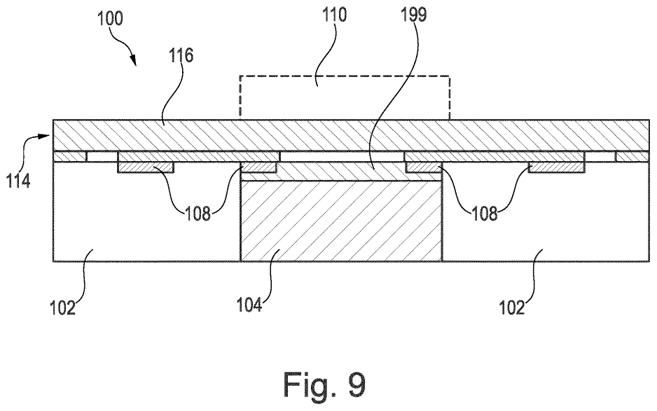

FIG. 9 illustrates a cross-sectional view of a package 100 according to another exemplary embodiment of the disclosure. According to FIG. 9, a redistribution layer 199 is formed directly on the glass inlay 104.

Since the glass material of the glass inlay 104 has a good performance to form a fine line structure, it may be possible to have redistribution layer 199 directly on the glass inlay 104. This may contribute to the formation of very fine line structures such as below 5 μm/5 μm line width/space. With this configuration, it may be possible to reduce the effort to form fine line structures on a component carrier-type package 100 with high yield. Furthermore, it may be possible to reduce the layer counts. Additionally, this may make it optionally possible to create the same level connection (as may be present between component 110 and carrier body 102) between the patterned glass inlay 104 and the carrier body 102. This can shorten the signal path along the carrier body 102, redistribution layer 199 on glass inlay 104 and component 110. No matter whether there is the same level connection between the glass inlay 104 and/or the carrier body 102 or not, with the redistribution layer 199 formed on the glass inlay 104 there may be a shorter signal path since the layer count may be reduced when the component 110 is mounted on the area above the glass inlay 104. Moreover, the glass inlay 104 with the redistribution layer 199 can be a good solution for providing a bridge function with more routing layers to support an interposer function in case of multiple components 110. This may involve a lower manufacturing effort than with a silicon interposer, a silicon bridge and a fine line redistribution layout on an organic component carrier. Moreover, taking this measure may support a function of the three-dimensional package 100 as a bridge.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A package, comprising:
a carrier body having a cavity;
a glass inlay embedded in the cavity of the carrier body;
a patterned metal layer on a main surface of the glass inlay; and
an electronic component mounted above the glass inlay.

2. The package according to claim 1, wherein the carrier body comprises an organic core.

3. (canceled)

4. The package according to claim 1, wherein a surface roughness Ra of the glass inlay is not more than 100 nm.

5. The package according to claim 1, wherein the carrier body comprises a further patterned metal layer at the same vertical level as the patterned metal layer on the glass inlay.

6. The package according to claim 1, wherein the glass inlay has a thickness in a range from 30 μm to 2000 μm.

7. The package according to claim 1, wherein a size of the glass inlay in a horizontal plane is larger than or equal to a size of the electronic component in a horizontal plane.

8. The package according to claim 1, wherein a difference between a horizontal surface area of the glass inlay and a horizontal surface area of the electronic component divided by the horizontal surface area of the glass inlay is not more than 50%.

9. The package according to claim 1, wherein the package comprises a top-sided layer build-up between the carrier body and the glass inlay on the one hand and the electronic component on the other hand.

10.-11. (canceled)

12. The package according to claim 1, wherein the package comprises a bottom-sided layer build-up below the carrier body and the glass inlay.

13. The package according to claim 12, wherein the bottom-sided layer build-up has regions of different thicknesses below the glass inlay and below the carrier body.

14. The package according to claim 8, wherein the top-sided layer build-up and the bottom-sided layer build-up are asymmetric.

15. The package according to claim 8, wherein the top-sided layer build-up has a higher integration density than the bottom-sided layer build-up.

17. The package according to claim 1, wherein the glass inlay comprises a silicon-based glass.

18. The package according to claim 1, wherein the only metallic material covering the glass inlay is said patterned metal layer on said glass inlay.

19. The package according to claim 1, wherein the electronic component is laterally misaligned with respect to the glass inlay so as to be arranged partially above the carrier body.

20. The package according to claim 1, wherein a difference between a height of the glass inlay and a height of the electronic component divided by the height of the glass inlay is less than 20%.

21. The package according to claim 1, wherein the package comprises a further electronic component mounted above the glass inlay.

22. The package according to claim 21, wherein the patterned metal layer is configured to function as a bridge between the electronic component and the further electronic component.

23. The package according to claim 1, wherein the patterned metal layer is formed in a design layer structure having a stamped surface profile.

24. The package according to claim 1, wherein the patterned metal layer is formed on a main surface of the glass inlay facing the electronic component.

25.-26. (canceled)
